(19) United States
(12) Patent Application Publication
(10) Pub. No.: US 2008/0003525 A1
(43) Pub. Date: Jan. 3, 2008

(54) Method for Projecting High Resolution Patterns

(75) Inventor: Kenji Amaya, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Tokyo Institute of Technology, Meguro-ku (JP)

(21) Appl. No.: 11/666,310

(22) PCT Filed: Oct. 14, 2005
(86) PCT No.: PCT/JP05/19362

§ 371 Date: Apr. 26, 2007

(30) Foreign Application Priority Data
Oct. 26, 2004 (JP) 2004-311218

(51) Int. Cl. H01L 21/027; G03F 7/20

(52) U.S. Cl. 430/311

(57) ABSTRACT

In a micro lithography using a photoresist, the invention provides a high resolution pattern projecting method which is not exposed to a proximity effect, by coating further a photochromic material on a surface of a photoresist layer, dividing a circuit pattern into plural image sub-sets, forming an image of the divided first sub-sets onto a substrate so as to expose the photoresist layer, thereafter recovering an absorption rate of the photochromic material to an initial state, thereafter forming an image of the divided next sub-sets onto the substrate so as to expose the photoresist layer, thereby repeatedly executing the formation with respect to all of the sub-sets, and forming the circuit patterns onto the photoresist layer on the substrate.

### TECHNICAL FIELD

The present invention relates to a method for projecting mask patterns onto a photoresist film used in a microlithography technique forming circuit patterns of LSI onto a semiconductor wafer (a silicone substrate), and more particularly to a method for projecting high resolution patterns which can form high resolution patterns.

### BACKGROUND ART

As a method for printing LSI circuit patterns on a silicone substrate, there is generally employed a method for reacting a photoresist on the substrate by irradiating a light such as a laser beam or the like to a master pattern (a mask). However, since a high density of the circuit is developed, and the same degree of wire width as a wavelength of the laser beam is demanded, it becomes hard to obtain a clear circuit pattern by a conventional method.

In other words, if the circuit pattern becomes thin to the wavelength level of the irradiated light, a projected image appears fuzzy, the images of the adjacent circuit patterns lap over each other, and there is generated a problem of “proximity effect” that it is hard to achieve a high resolution. A description will be given specifically of this matter according to FIG. 1.

If the light (generally employing an ultraviolet light) is irradiated onto the silicone substrate on which the photoresist is coated, through a photomask (corresponding to a negative film, hereinafter, refer simply to as “mask”) on which the circuit pattern is formed, the photoresist in an area in which a light intensity is over a predetermined value (called as a threshold value) is exposed near an aperture of the mask. However, if the light is irradiated simultaneously to two apertures close to each other, the lights do not independently reach the threshold value, however, an amount of exposure is summed up in a portion (a range (i) in FIG. 1) where the lights from two apertures overlap, so that the lights get over the threshold value. Accordingly, the photoresist is exposed. This causes an indistinctness of the image and a reduction of the resolution. This is caused by a nature that a material of the photoresist follows a reciprocity law, that is, the material of the photoresist is exposed absolutely equally in the case that a product of an illumination intensity times an exposure time (=exposure amount) is uniform.

In order to avoid the problem of the proximity effect mentioned above, there is considered a method of dividing the mask into plural sections, in such a manner that the apertures of the mask are not close to each other. A description will be given of this matter with reference to FIG. 2. That is, as shown in FIG. 2(A), if the exposure is executed first by a first divided mask, only the portion exposed to the light having the intensity more than the threshold value is exposed, a portion exposed to a stray light is not exposed to be dissolved in a liquid developer but generates a chemical change at a degree corresponding to an amount of the exposed light, and the chemical change is stored. This is called as “memory effect”.

Next, if a second time exposure is executed by using a second mask after an interval of time, the portion exposed to the light having the strength more than the threshold value in the photoresist is exposed, and a portion (ii) in FIG. 2(B) in the portion exposed to the stray light is exposed because the exposure amount stored at a time of the first time exposure and the exposure amount exposed at a time of the second time exposure are summed so as to get over the threshold value in accordance with the reciprocity law mentioned above. As a result, since the photoresist has the nature of storing the exposure amount, it is impossible to ignore a diffraction and proximity effect of the light.

As a method of solving the problem, there have been conventionally executed a development of a new laser beam having a short wavelength, and an improvement of the mask pattern, however, there is a problem that it is expensive to develop and newly introduce the equipment.

Further, as a method for image forming the patterns onto the photoresist layer directly by operating a reflected light without using the photomask mentioned above, there has been known a maskless lithography method using a digital micro mirror array (refer to Journal of Microlithography, Microfabrication and Microsystems, October 2003, Volume 2, Issue 4, pp. 331-339 High-resolution maskless lithography, Kin Foong Chan, Zhiquiang Feng, Ren Yang, Akihito Ishikawa, and Wenhui Mei). This is structured such as to directly form the image corresponding to the circuit patterns on the photoresist layer by the reflected light by operating the digital micro mirror array. In this case, in place of dividing the mask, the pattern to be irradiated is previously divided into plural image sub-sets (of course, divided in such a manner that the adjacent patterns do not enter into the same sub-sets), and the exposure is executed in each of the sub-sets. However, the diffraction and the proximity effect of the light are not negligible, in the same manner as the case that the mask is divided.

Accordingly, as a method of drastically solving the problems, there has considered a method of using a thermo resist as an etching resist (refer to Japanese Patent Publication No. 2000-228357). The thermo resist corresponds to a material which becomes soluble in the case that a temperature gets over a certain threshold value in accordance with a reaction to the heat. The thermo resist is greatly different from the conventional photoresist in a point that the thermo resist does not follow a linear proximity law, so that the thermo resist is not affected by the diffraction and the proximity effect of the light. The resist which does not follow the reciprocity law as mentioned above is called as a “reciprocity law failure resist”.

However, the reciprocity law failure resist represented by the thermo resist or the like is greatly inferior to the photoresist which is actually used at the present, in points of a transparency, a high sensitivity, a reactivity, an alkaline development, a heat resistance, an etching resistance and the like which correspond to performances required by the microlithography. With respect to the reciprocity law failure resist for the microlithography, there have been hardly executed detail researches about the performances such as the sensitivity, the alkaline development, the heat resistance, and the etching resistance and the like.

Accordingly, for example, it is necessary to strengthen the intensity of the irradiation laser and elongate the irradiating time for compensating the sensitivity performance. In accordance with the condition changes, there is generated a collateral problem such that a wafer becomes high temperature, a production efficiency is lowered and the like.

On the other hand, the photoresist has been enormously researched and developed and is actually utilized in the microlithography, and it is desired that the photoresist is not affected by the diffraction and proximity effect of the light such as the reciprocity law failure resist while being utilized.

### DISCLOSURE OF THE INVENTION

### Problem to be solved by the Invention

The present invention is made by taking the circumstances mentioned above into consideration, and an object of the present invention is to provide a method for projecting patterns without being affected by a proximity effect, in a microlithography using a conventional photoresist.

### Means for Solving the Problem

The present invention relates to a pattern projecting method for increasing a resolution without being affected by a proximity effect, in a microlithography using a photoresist. The object of the present invention can be achieved by a pattern projecting method for forming an image of circuit patterns onto a substrate on which a negative or positive photosensitive photoresist layer is laminated, in accordance with an exposure, exposing the photoresist layer and thereafter developing the photoresist layer, thereby forming the circuit patterns onto the photoresist layer on the substrate, comprising the steps of:

coating further a photochromic material on a surface of the photoresist layer in a stage prior to the exposure;

dividing the circuit pattern into plural image sub-sets;

forming an image of the divided first sub-sets onto the substrate so as to expose the photoresist layer;

thereafter recovering an absorption rate of the photochromic material to an initial state by irradiating a light having a different wavelength from that of the irradiated light or heating to a predetermined temperature or leaving at a room temperature for a predetermined time;

thereafter forming an image of the divided next sub-sets onto the substrate so as to expose the photoresist layer, thereby repeatedly executing the formation with respect to all of the sub-sets; and

forming the circuit patterns onto the photoresist layer on the substrate.

Further, the object mentioned above of the present invention can be achieved by respectively laminating bismuth and indium metal thin films in place of the photochromic material, executing an exposure thereto, and generating a bismuth-indium alloy on the basis of a temperature increase caused by the exposure so as to transparentize the metal thin film, thereby exposing the photoresist layer.

Further, the object mentioned above of the present invention can be achieved by forming a multi-layer thin film made of the material having a low-melting point such as a wax or a dibutyl phenol or the like so as to form an interference filter, in place of the photochromic material, increasing a temperature of the thin film on the basis of the exposure, liquefying the multi-layer thin film and removing an interference function so as to transmit the light, thereby exposing the photoresist layer.

This method includes both of a method using a photomask, and a maskless lithography method using a digital micro mirror array, which directly forms the patterns onto the photoresist layer by operating the reflected light without using the photomask.

Further, the object mentioned above of the present invention can be further effectively achieved by spin coating the applying method of the photochromic material, or executing the exposure by a reduced projection exposure by a stepper.

### BRIEF DESCRIPTION OF THE DRAWINGS

FIG. 1 is a view for explaining an influence of a proximity effect;

FIG. 2 is a view for explaining an influence of a memory effect;

FIG. 3 is a view showing a state in which a photochromic material is further laminated on a photoresist layer laminated on a silicone substrate;

FIG. 4 is a view for explaining a method for projecting high resolution patterns in accordance with the present invention;

FIG. 5 is a view showing a difference of resolution between the conventional method and the method in accordance with the present invention;

FIG. 6 is a view showing a structure in which one circuit pattern is divided into plural different sub patterns structured by independent unit patterns having the same shape;

FIG. 7 is a view showing a design example of an OPC and a PSM with respect to a square unit pattern;

FIG. 8 is a view showing a secondary mask for generating the sub patterns by combining with a master mask shown in FIG. 6;

FIG. 9 is a view showing a state in which respective bismuth and indium metal thin films are laminated on a photoresist layer at a thickness of about 20 nm; and

FIG. 10 is a view showing a state in which two layers of interference filters are formed on a surface of the photoresist layer.

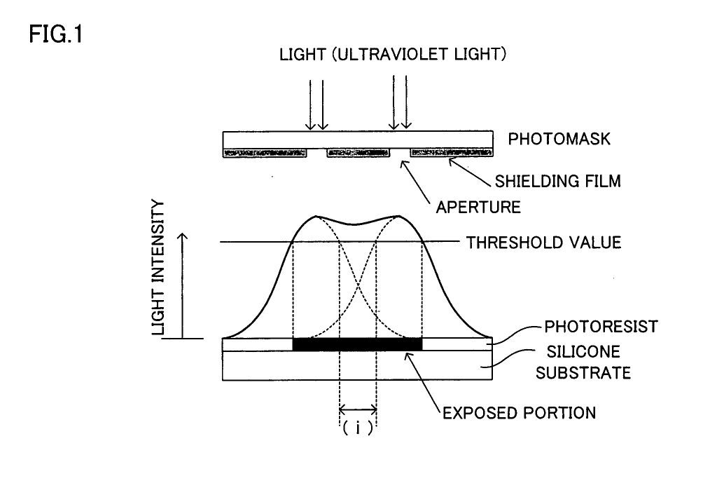

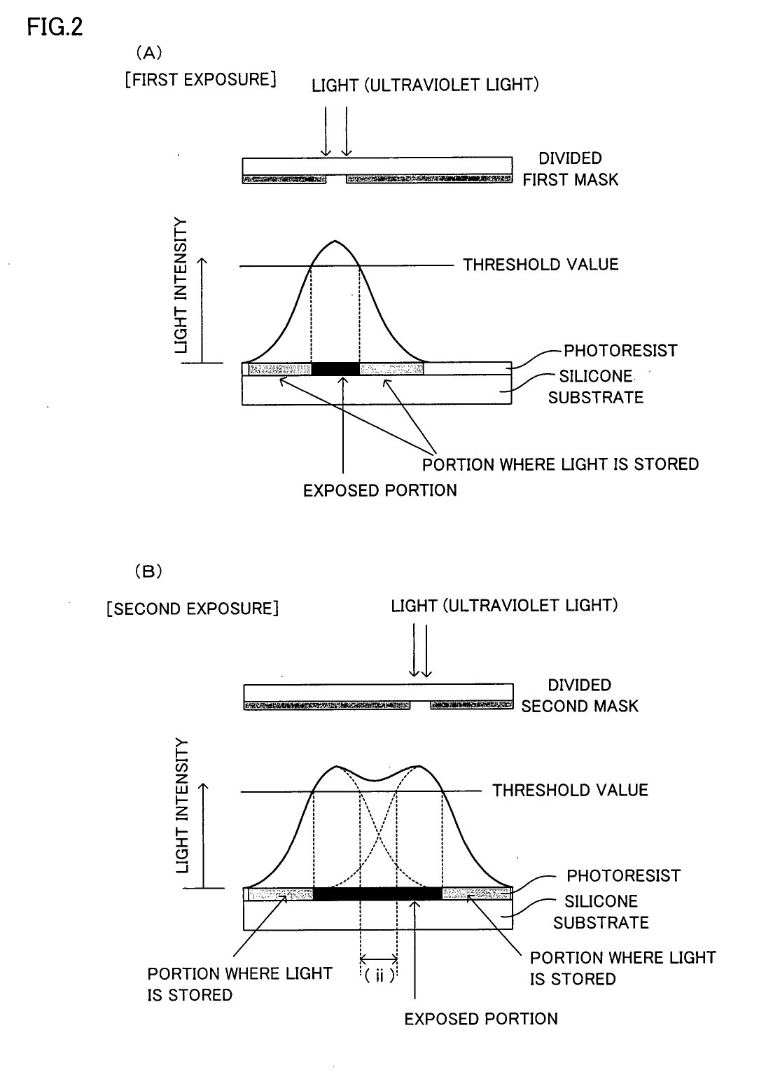

### EFFECT OF THE INVENTION

In accordance with the method for projecting the high resolution patterns on the basis of the present invention, since the circuit pattern is divided into plural sub-sets so as to be exposed, and the photochromic material is coated on the photoresist layer, it is possible to project the high resolution patterns without any diffraction and proximity effect of the light while using the photoresist such as the conventional one. That is, if the pattern is divided into plural sections and the light is irradiated, the blurredly expanded portion having the small light intensity (the portion equal to or less than the threshold value) is shielded by the layer of the photochromic material, and the light is not applied to the photoresist. Accordingly, it is possible to prevent the proximity effect.

Further, it is possible to prevent the proximity effect by applying the exposure to the bismuth-indium laminated thin layer and the multilayer thin film of the material having low melting point such as the wax or the like, thereby transmitting the light only to the portion to which the light equal to or more than the threshold value is applied.

### BEST MODE FOR CARRYING OUT THE INVENTION

The present invention is characterized in that an image of projected circuit patterns is divided into plural sub-sets so as to be exposed, and a proximity effect is removed by utilizing a reversible photo-functional material called as a photochromic material in which an absorption rate is changed by being exposed to the light and the absorption rate is turned back for an interval of time. In other words, the exposure is applied to a structure in which the photochromic material which becomes transparent if the exposed light becomes equal to or more than “threshold value” and is reversibly changed to the original opaque state for an interval of time is coated on the photoresist layer. In this case, it is possible to recover the absorption rate of the photochromic material to the initial state by executing an irradiation of the light having the different wavelength from that of the irradiated light or a heating to a predetermined temperature, in place of leading for a predetermined time.

As the photochromic material having the nature mentioned above, there has been known an indoline spiropiran corresponding to a photochromic spiropiran material, and a material obtained by dispersing this into a transparent polymer (for example, an urethane or the like) serving as a base material is coated on the photoresist layer. The indoline spiropiran has a nature that an absorption rate is lowered by a light response at a time of irradiating the light, and the absorption rate is increased by a heat reaction (refer to Chemical of Organic Photochromism, issued by Chemical Society of Japan, planned and edited by Masahiro Irie, Kunihiro Ichimura, Yasushi Yokoyama, Junichi Hibino and Akio Taniguchi).

Specifically, spiroselenazorinobenzopiran (one kind of indoline spiropiran) is mixed with the urethane rubber, and dissolved in DMF solvent so as to be spin coated on the photoresist.

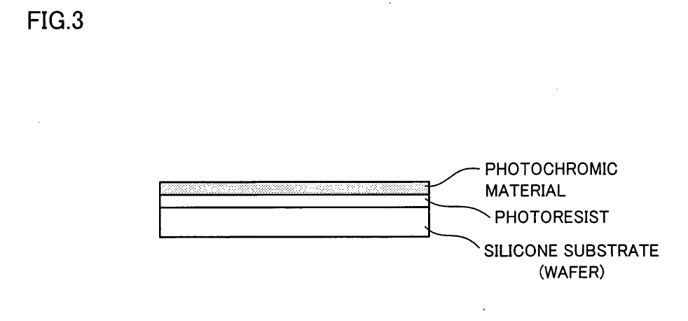

FIG. 3 shows a state in which the photochromic material is further laminated on the photoresist layer laminated on the silicone substrate. A laminating way of the photochromic material can use a spin coat used for forming the photoresist layer.

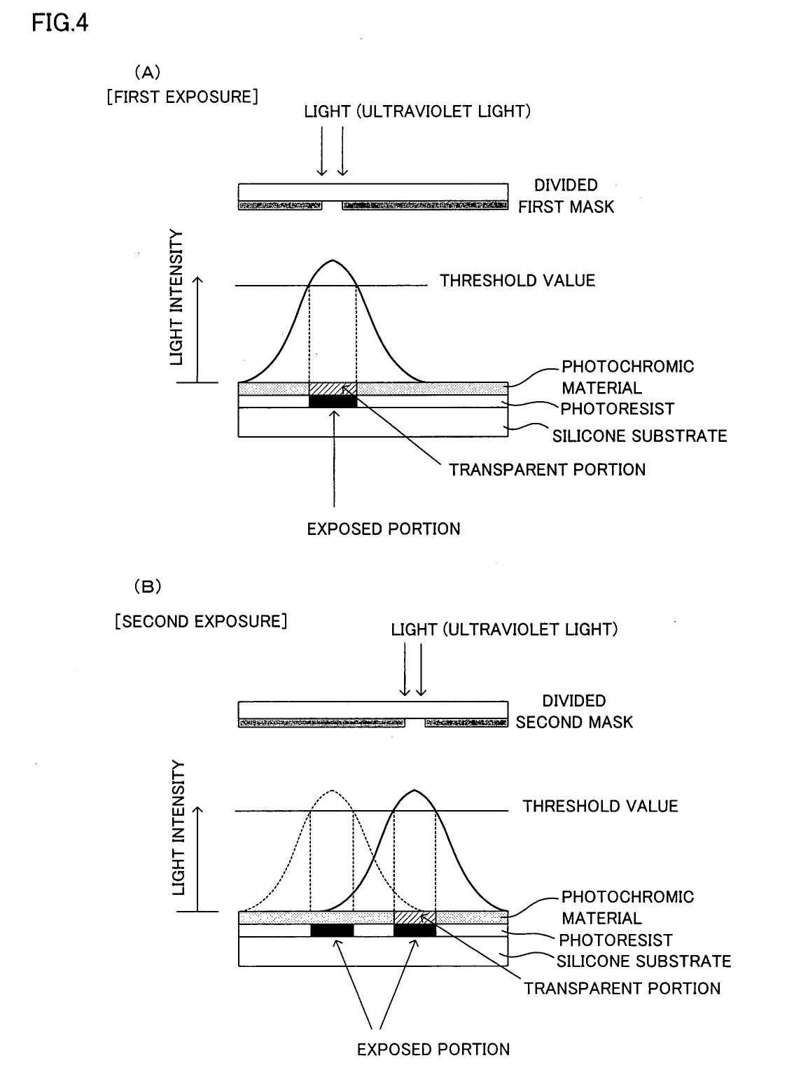

A description will be given of a method of projecting high resolution patterns in accordance with the present invention with reference to FIG. 4.

First, as shown in FIG. 4(A), if a first exposure is executed by the first divided mask, the photochromic material is changed to be transparent only in a portion which is exposed to the light having the intensity over the threshold value, and the light having the intensity more than the threshold value transmit. Accordingly, the photoresist is exposed. Since the portion exposed to the stray light is kept opaque (equal to or less than the threshold value), the light does not reach the photoresist layer, and the conventional memory effect is not generated.

Next, when a second exposure is executed by using the second mask after a time, the photochromic material is returned to the original opaque state. If the second exposure is executed under this state (FIG. 4(B)), the photochromic material is changed to be transparent only in the portion which is exposed to the light having the strength more than the threshold value, and the light having the intensity more than the threshold value transmits. Accordingly, the photoresist is exposed. Since the portion exposed to the stray light is kept opaque (equal to or less than the threshold value), the light does not reach the photoresist layer, and the conventional memory effect is not generated.

On the final analysis, even if the photoresist has a nature storing the exposure amount, the stray light is blocked off by the photochromic material, and does not reach the photoresist layer, so that there is not generated a problem of the proximity effect. Accordingly, it is possible to achieve the high resolution pattern projection.

In this case, the description mentioned above corresponds to the example in which the exposure is executed by using the divided photomask, however, the same matter is applied to the maskless lithography method using no photomask, a description thereof will be omitted.

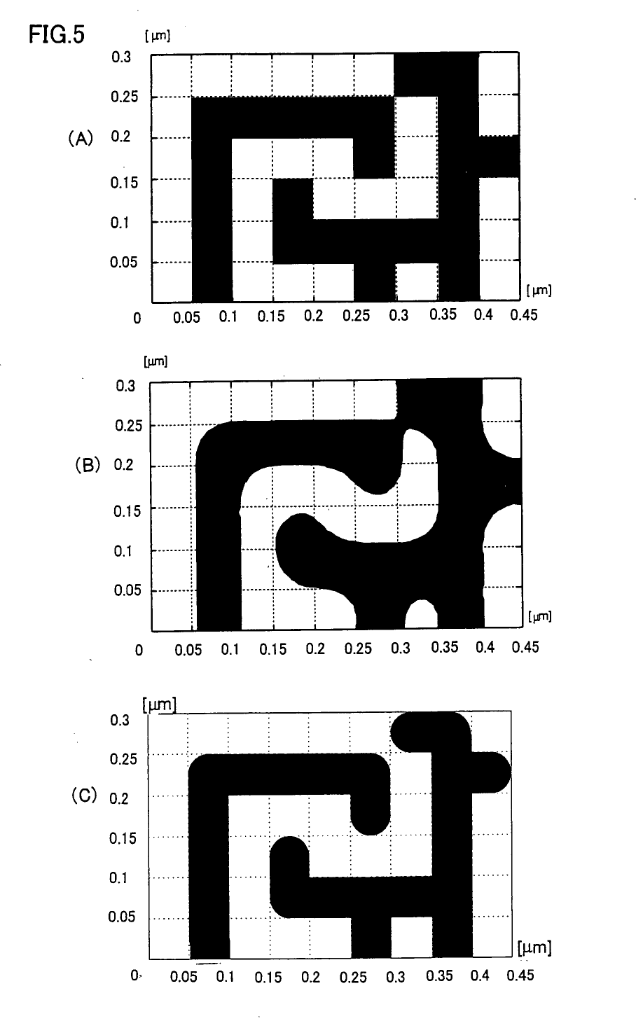

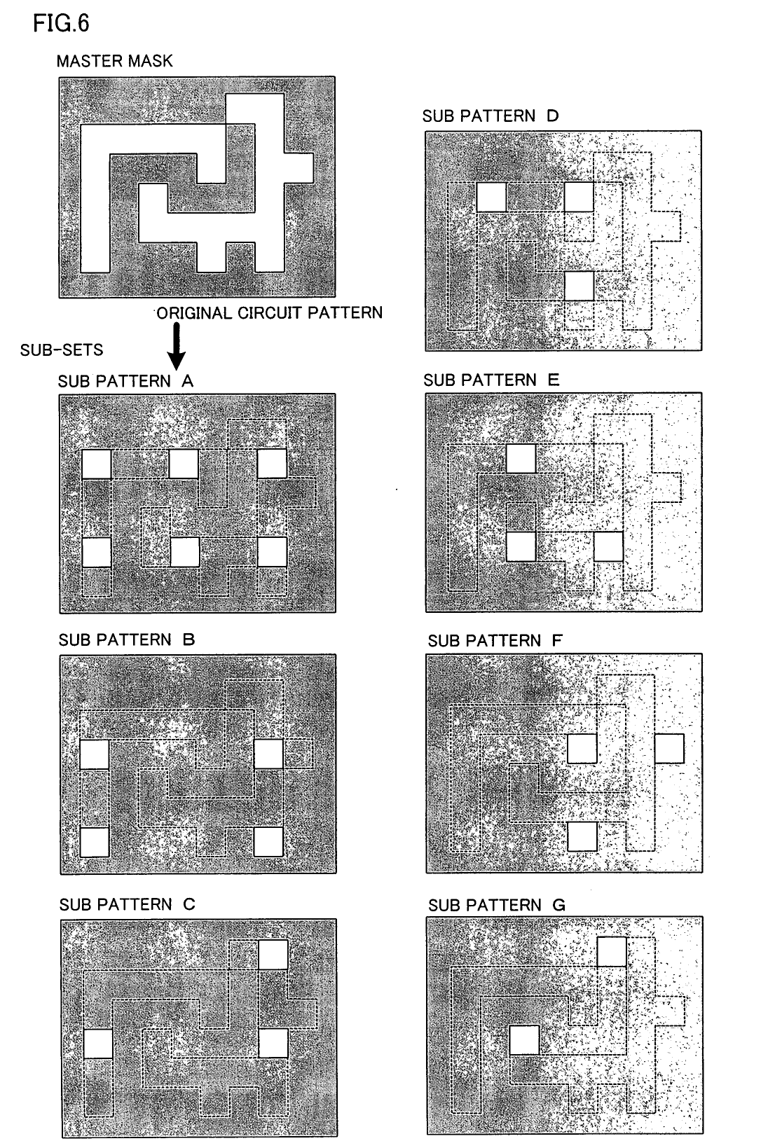

Further, in the present invention, as shown in FIG. 6, the high resolution pattern projection can be achieved by using the patterns of the sub-sets obtained by dividing the original circuit patterns to be projected into plural different sub patterns A to G constituted by the independent unit patterns (the unit square pattern). In this case, it is necessary that the unit patterns are got off in such a level that the stray light is not affected.

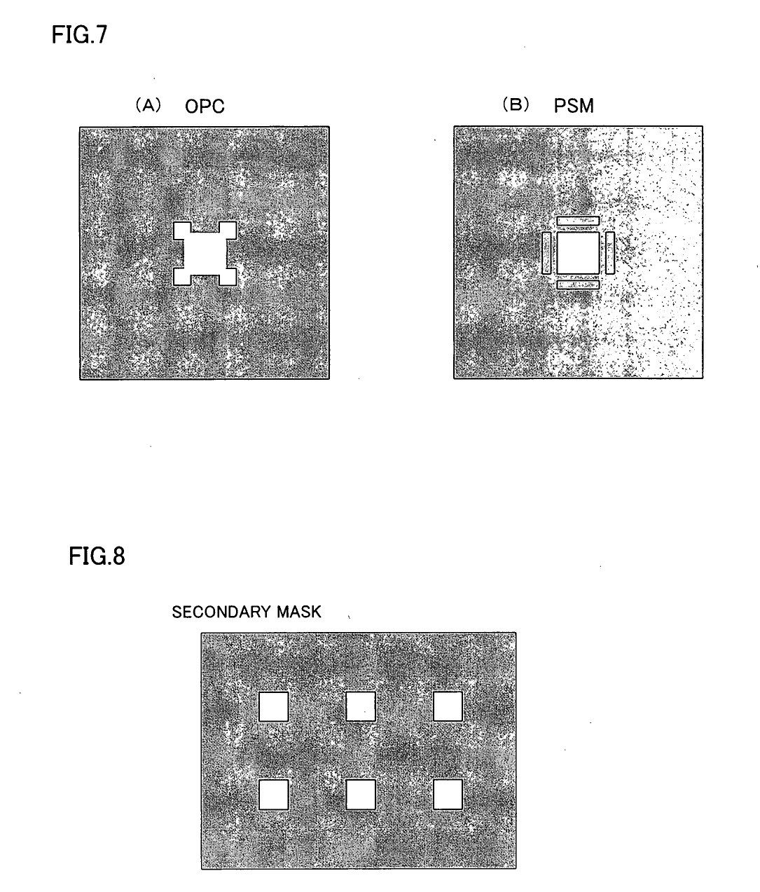

In other words, since the unit patterns having the same shape are used, it is possible to execute the control of the threshold value of the exposure reaction, the design of the phase shift mask (PSM), the design of the proximity effect correction (OPC) and the like, only by executing the operations with regard to one unit pattern. Accordingly, there is an advantage that a degree of freedom of the design is increased. Further, it is possible to expect a rapid operation and a cost saving of a mask designing, developing and manufacturing step. FIG. 7 shows a design example of an OPC and a PSM with respect to the square unit pattern. FIGS. 7(A) and 7(B) respectively show the design examples of the OPC and the PSM.

In this case, the sub-sets patterns may respectively use the patterns formed as the independent sub masks, however, it is efficient to lap a secondary mask as shown in FIG. 8 on a master mask on which the original circuit pattern as shown in FIG. 6 is formed, and project an image of the sub-sets patterns onto the mask while relatively moving the secondary mask.

Further, as a method of forming the image of the pattern of the sub-sets only the photoresist layer without using the photomask of plural sub-sets mentioned above, there is a method of executing the exposure by using a micro lens array.

In this case, the substrate is explained by exemplifying the silicone substrate, however, can employ any substrate on which the patterns can be formed by etching, for example, it is possible to employ a circuit substrate of a liquid display panel.

Further, the present method can be utilized as it is in a reduced projection exposure apparatus called as a stepper.

The description is given of the method of removing the proximity effect by applying the photochromic material to the photoresist layer, however, the same effect can be obtained by using the other materials in place of the photochromic material. A description will be given below of two cases.

(1) A method of laminating each of metal thin films of bismuth and indium onto the surface of the photoresist layer.

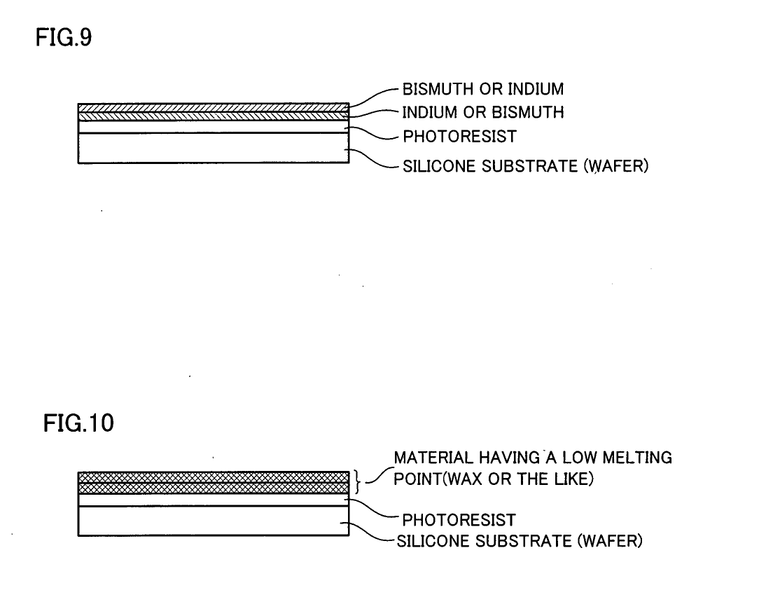

Specifically, as shown in FIG. 9, it corresponds to a method of laminating each of the metal thin films of bismuth and indium onto the photoresist layer at a thickness of about 20 nm, exposing it by using the photomask or the micro lens array, changing the laminated thin film to a bismuth-indium alloy on the basis of a temperature increase caused by the exposure so as to make the laminated thin film transparent, and exposing the photoresist layer. The reaction occurs near 100° C., however, this temperature is achieved by using the current stepper.

Further, since the memory effect is not applied to the area having the threshold temperature or less forming the alloy, in the metal thin film, the problem of the proximity effect is not generated.

(2) A method of constructing an interference filter by further forming a multilayer thin film made of the material having a low melting point such as a wax, a dibutyl phenol or the like on the surface of the photoresist layer.

The interference filter corresponds to an optical filter selectively transmitting the light having a specific wavelength range, by utilizing an interference effect of the multilayer thin film, normally uses a material having a strong heat resistance for coating, however, is characterized by inversely using the material having a low melting point such as the wax or the like in the present invention.

In other words, a temperature of the thin film is increased by the exposure, only the portion reaching the melting point is liquefied so as to lost the interference function, and the light transmits. It corresponds to a method of exposing the photoresist layer by the transmitting light. Since the exposure area (the area to which the stray light is applied) having the low intensity which does not reach the melting point is returned to the original state on the basis of the reduction of the temperature, the memory effect does not work, and the problem of the proximity effect is not generated. In this case, needless to say, the intensity of the light is adjusted such that an ideal exposure area gets over the melting point, and the area to which the stray light is applied does not get over the melting point.

Further, it is preferable that a number of the thin film layers is set to two in the light of the efficiency of the steps. FIG. 10 is a view showing a state in which two layers of interference filters are formed on the surface of the photoresist layer.

### Embodiment

FIG. 5 is a simulation view comparing an edge shape between a case of using the high resolution pattern projecting method in accordance with the present invention, and a case of using the conventional method (the method of directly exposing the photoresist).

FIG. 5(A) shows an original circuit pattern, FIG. 5(B) shows a result of projection in accordance with the conventional method, and FIG. 5(C) shows a result of projection in accordance with the method of the present invention. In FIG. 5(C), it is known that the influence by the proximity effect is not generated, and the projection of the patterns having the high resolution is executed.

What is claimed is:

1. A high resolution pattern projecting method for forming an image of circuit patterns onto a substrate on which a negative or positive photosensitive photoresist layer is laminated, in accordance with an exposure, exposing the photoresist layer and thereafter developing the photoresist layer, thereby forming the circuit patterns onto the photoresist layer on the substrate, comprising the steps of:
coating further a photochromic material on a surface of the photoresist layer in a stage prior to the exposure;
dividing the circuit pattern into plural image sub-sets;
forming an image of the divided first sub-sets onto the substrate so as to expose the photoresist layer;
thereafter recovering an absorption rate of the photochromic material to an initial state by irradiating a light having a different wavelength from that of the irradiated light, heating to a predetermined temperature, or leaving at a room temperature for a predetermined time;
thereafter forming an image of the divided next sub-sets onto the substrate so as to expose the photoresist layer, thereby repeatedly executing the formation with respect to all of the sub-sets; and
forming the circuit patterns onto the photoresist layer on the substrate.

2. A high resolution pattern projecting method according to claim 1, wherein the method of applying the photochromic material is constituted by a spin coat.

3. A high resolution pattern projecting method for forming an image of circuit patterns onto a substrate on which a negative or positive photosensitive photoresist layer is laminated, in accordance with an exposure, exposing the photoresist layer and thereafter developing the photoresist layer, thereby forming the circuit patterns onto the photoresist layer on the substrate, comprising the steps of:
laminating further bismuth and indium metal thin films on a surface of the photoresist layer in a stage prior to the exposure;
dividing the circuit pattern into plural image sub-sets;
forming an image of the divided first sub-sets onto the substrate so as to expose the photoresist layer; and
forming the circuit patterns onto the photoresist layer on the substrate.

4. A high resolution pattern projecting method for forming an image of circuit patterns onto a substrate on which a negative or positive photosensitive photoresist layer is laminated, in accordance with an exposure, exposing the photoresist layer and thereafter developing the photoresist layer, thereby forming the circuit patterns onto the photoresist layer on the substrate, comprising the steps of:
forming further a multilayer thin film made of material having a low meting point on a surface of the photoresist layer in a stage prior to the exposure so as to form an interference filter;
dividing the circuit pattern into plural image sub-sets;
forming an image of the divided first sub-sets onto the substrate so as to expose the photoresist layer; and
forming the circuit patterns onto the photoresist layer on the substrate.

5. A high resolution pattern projecting method according to any one of claims 1 to 4, wherein the sub-sets are structured by dividing the circuit pattern into plural different divided sub patterns constituted by independent unit patterns having the same shape.

6. A high resolution pattern projecting method according to any one of claims 1 to 5, wherein the exposure is constituted by a reduced projection exposure generated by a stepper.

7. An integrated circuit, wherein a circuit pattern is projected by the method according to any one of claims 1 to 6, and the circuit pattern is formed on the substrate.

8. A liquid crystal display panel, wherein a circuit pattern is projected by the method according to any one of claims 1 to 6, and the circuit pattern is formed on the substrate.
